(19) United States
(12) Patent Application Publication
(10) Pub. No.: US 2012/0235115 A1
(43) Pub. Date: Sep. 20, 2012

(54) GROWTH OF III-V LED STACKS USING NANO MASKS

(75) Inventors: Sang Won Kang, San Jose, CA (US); Jie Su, Edison, NJ (US); Tuoh-Bin NG, San Jose, CA (US); David Bour, Cupertino, CA (US); Wei-Yung Hsu, San Jose, CA (US)

(73) Assignee: APPLIED MATERIALS, INC., Santa Clara, CA (US)

(21) Appl. No.: 13/355,255

(22) Filed: Jan. 20, 2012

Related U.S. Application Data
(60) Provisional application No. 61/435,512, filed on Jan. 24, 2011.

(51) Int. Cl. H01L 21/205; C23C 16/34; C23C 16/52; H01L 33/06

(52) U.S. Cl. 257/13; 438/478; 118/715; 118/712; 257/E33.008; 257/E21.11

(57) ABSTRACT

Methods, semiconductor material stacks and equipment for manufacture of light emitting diodes (LEDs) with improve crystal quality. A growth stopper is deposited between nuclei for a group III-V material, such as GaN, to form a nano mask. The group III-V material is laterally overgrown from a region of the nuclei not covered by the nano mask to form a continuous material layer with reduced dislocation density in preparation for subsequent growth of n-type and p-type layers of the LED. The lateral overgrowth from the nuclei may further recover the surface morphology of the buffer layer despite the presence of the nano mask. Presence of the growth stopper may further result in void formation on a substrate side of an LED stack to improve light extraction efficiency.

### CLAIM OF PRIORITY

This application is related to, and claims priority to, the provisional utility application entitled “Growth of III-V LED Stacks Using Nano Masks,” filed on Jan. 24, 2011, having an application No. 61/435,512 (Attorney Docket No. 016114L/AEP/NEON/ESONG), the entire contents of which are incorporated herein by reference.

### BACKGROUND

1. Field

Embodiments of the present invention pertain to the field of light-emitting diode (LED) fabrication and, in particular, to growing group III-V epitaxial LED material stacks with a nano mask.

2. Description of Related Art

Group III-V materials are playing an ever increasing role in the semiconductor and related, e.g. light-emitting diode (LED), industries. While LEDs employing multiple quantum well (MQW) structures epitaxially grown on a substrate are a promising technology, epitaxial growth of such structures is difficult because device efficiency is a function of the density of crystallographic defect within the device. For example, a higher density of defects (e.g., screw dislocations), in the lattice can reduce internal quantum efficiency.

Significant work has been performed to reduce the defect density in material systems offering benefits for LED applications, such as gallium nitride (GaN). For example, much effort has been expended on development of various buffers for an LED stack grown on sapphire or even silicon substrates. Various techniques have been applied to reduced defect densities in layers of the LED material stack, however many techniques which have been found to reduce defect densities in epitaxial material layer have also been found to degrade the surface morphology such that the material layer surface becomes rough, as often characterized via a reduction in reflectance. As degradation of surface morphology is also detrimental to LED performance, many options for reducing defect densities that are suitable in stacks grown for other device applications (e.g., transistors) are inadequate for stacks grown for LED applications.

Growth techniques, stacks generated by such techniques, and processing equipment for performing the techniques which address these problems, as described herein, are therefore advantageous.

### BRIEF DESCRIPTION OF THE DRAWINGS

Embodiments of the present invention is illustrated by way of example, and not by way of limitation, in the figures of the accompanying drawings, in which:

FIG. 1A illustrates a cross-sectional view of a GaN-based LED film stack which may be grown using a nano mask, in accordance with an embodiment of the present invention;

FIG. 1B is a flow diagram illustrating a general method for growing certain layers of an LED stack using a nano mask, in accordance with an embodiment of the present invention;

FIG. 1C depicts cross-sectional views of a portion of an GaN-based LED film stack as particular operations in the nano masking method depicted in FIG. 1B are performed on a substrate, in accordance with an embodiment of the present invention;

FIG. 2A is an XRD rocking curve for a layer of GaN grown using a conventional growth technique;

FIG. 2B is an XRD rocking curve for a layer of GaN grown using the nano masking method depicted in FIG. 1B, in accordance with an embodiment.

FIG. 3 is a schematic cross-sectional view of an MOCVD apparatus, in accordance with an embodiment of the present invention; and

FIG. 4 is a schematic of a computer system, in accordance with an embodiment of the present invention.

### SUMMARY

Light-emitting diodes (LEDs) and related devices may be fabricated from layers of group III-V films. Exemplary embodiments of the present invention relate to the growth of group III-V materials with particular embodiments illustrating application to group III-nitride films, such as, but not limited to gallium nitride (GaN) films. Methods, semiconductor material stacks and equipment for the manufacture of LEDS with improved crystalline quality are described herein.

In an embodiment, a growth stopper is deposited between nuclei for a group III-nitride material, such as GaN, to form a nano mask. The group III-nitride material is laterally overgrown from an upper region of the nuclei not covered by the nano mask to form a continuous material layer with reduced dislocation density in preparation for subsequent growth of n-type and p-type layers of the LED. The lateral overgrowth from the nuclei may further recover the surface morphology of the buffer layer despite the growth stopper. Presence of the growth stopper may further result in void formation on a substrate side of an LED stack to improve light extraction efficiency.

In an embodiment, during a nucleation growth operation in a deposition chamber, islands of a group III-nitride material are grown over a semiconductor buffer layer to form nuclei for subsequent epitaxial growth. A nano mask is then formed by depositing a growth stopper between the nuclei to cover the surface of the buffer layer not covered by the nuclei. During a recovery growth operation, a group III-nitride material is epitaxially overgrown from a region of each of the nuclei left uncovered by the growth stopper to bridge the nuclei above the nano mask.

Embodiments include an LED semiconductor material stack including a buffer layer, such as a group III-nitride, disposed over a substrate, such as sapphire. Over the buffer layer is a disposed a plurality of nuclei separated from each other by a growth stopper. An n-type and a p-type group III-nitride layer is disposed over the nucleation layer, and in certain embodiments a multiple quantum well structure is disposed between the n-type and p-type layer.

Embodiments include a deposition chamber and a system controller to introduce a group III source gas and a nitrogen source gas into the deposition chamber to epitaxially grow islands of a group III-nitride material over a buffer layer and form nuclei during a nucleation operation. The system controller is further to replace the group III source gas introduced into the deposition chamber during formation of the nuclei with a silicon source gas while continuing to introduce into the deposition chamber the nitrogen source gas utilized during formation of the nuclei to form a nano mask layer between the nuclei in-situ with the nucleation operation. In further embodiments, the system controller is further to replace the silicon source gas with the group III source gas to bridge the nuclei above the nano mask layer with a continuous layer of the group III-nitride material in-situ with the nano mask layer formation.

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

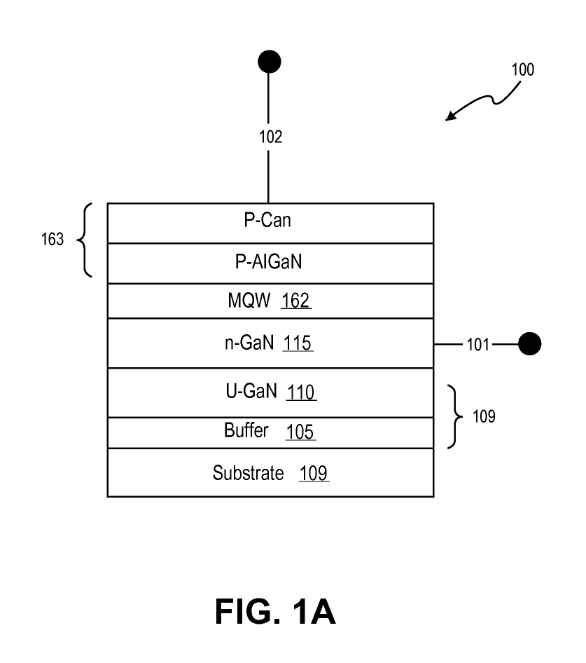

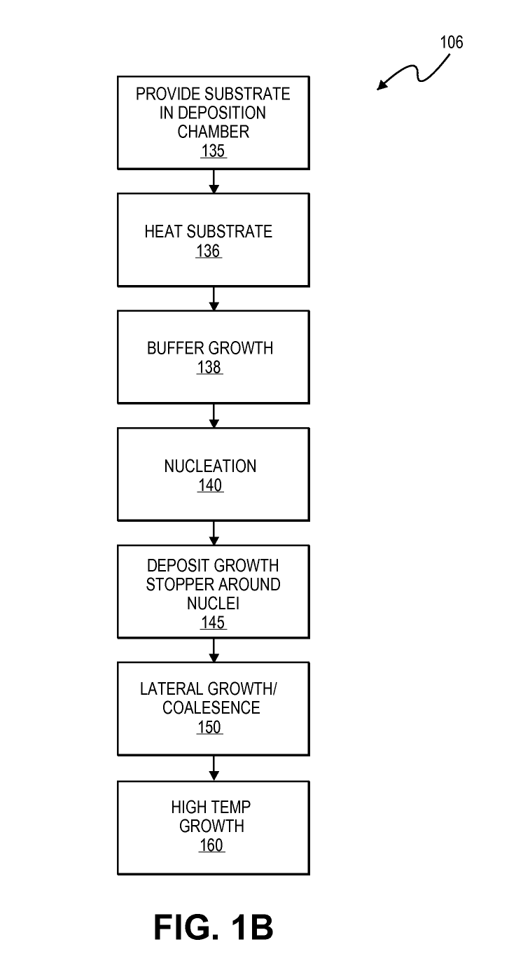

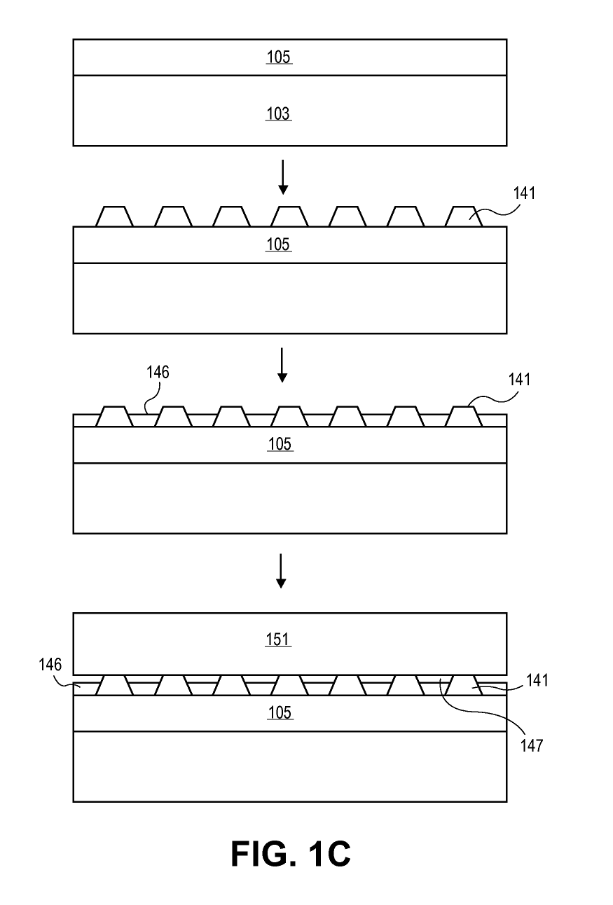

FIG. 1A illustrates a cross-sectional view of a LED incorporating a GaN-based LED film stack which may be grown using the nano masking method depicted in FIG. 1B, in accordance with an embodiment of the present invention. Depending on the embodiment, all layers in a III-V LED stack, such as that in the LED depicted in FIG. 1A, are grown with a single chamber process or a multiple chamber process. For a single chamber process, layers of differing composition are grown successively as different steps of a growth recipe executed within the single chamber. For a multiple chamber process, layers are grown in a sequence employing separate chambers. For example, and undoped and/or a nGaN layer may be grown in a first chamber, a MQW structure in a second chamber, and a pGaN layer grown in a third chamber.

In FIG. 1A, an LED stack is formed on a substrate 103. In one implementation, the substrate 103 is single crystalline sapphire (e.g., (0001)) and may be patterned or unpatterned. Other embodiments contemplated include the use of substrates other than sapphire substrates, such as, Silicon (Si), germanium (Ge), silicon carbide (SiC), gallium arsenide (GaAs), zinc oxide (ZnO), lithium aluminum oxide (γ-LiAlO₂).

Upon the substrate 103, are one or more support layers for a p-n junction formed thereon. A transition or buffer layer 105 is formed on the substrate to facilitate transition of crystallographic and thermal properties between the substrate 103 and the LED device layers. The buffer layer 105 is generally to be of a material which includes crystalline nuclei domains within amorphous regions. Exemplary buffer materials include group III-nitride based materials, such as, but not limited to, GaN, InGaN, AlGaN. Exemplary thicknesses of the buffer layer 105 are in the range of 10 nm to 200 nm depending on the material with one GaN buffer embodiment being in the range of 10 nm to 20 nm.

As further illustrated in FIG. 1A, the LED stack includes an undoped layer 110 disposed over the buffer layer 105 to form a base layer stack 109. The undoped layer 110 is to be of a good quality and substantially single crystalline, as epitaxially grown from the crystalline nuclei domains in the buffer layer 105, with as low of defect density as possible so that the LED device layers disposed over the undoped layer may also be of a lowest possible defect density to provide a high quantum efficiency. The base layer stack 109 and the operations to form the base layer stack 109 are described in greater detail elsewhere herein.

One or more bottom n-type epitaxial layer 115 is further included in the LED stack incorporated into the LED 100. In the exemplary group III-nitride material system, the bottom n-type epitaxial layer 115 may be any n-type group III-nitride based material, such as, but not limited to, GaN, InGaN, AlGaN.

Disposed on the n-type epitaxial layer 115 is a multiple quantum well (MQW) structure 162. The MQW structure 162 may be any known in the art to provide a particular emission wavelength. In a certain embodiments, the MQW structure 162 may have a wide range of indium (In) content within GaN. For example, depending on the desired wavelength(s), the MQW structure 162 may have between about a 10% to over 40% of mole fraction indium as a function of growth temperature, ratio of indium to gallium precursor, etc. It should also be appreciated that any of the MQW structures described herein may also take the form of single quantum wells (SQW) or double hetereostructures that are characterized by greater thicknesses than a QW. The MQW structure 162 may be grown in a metalorganic chemical vapor deposition (MOCVD) chamber or a hydride/halide vapor phase epitaxy (HVPE) chamber, or another known in the art. Any growth techniques known in the art may be utilized with such chambers.

One or more p-type epitaxial layers 163 are disposed over the MQW structure 162. The p-type epitaxial layers 163 may include one or more layers of differing material composition. In the exemplary embodiment depicted in FIG. 1A, the p-type epitaxial layers 163 include both p-type GaN and p-type AlGaN layers doped with Mg. In other embodiments only one of these, such as p-type GaN are utilized. Other materials known in the art to be applicable to p-type contact layers for GaN systems may also be utilized. The thicknesses of the p-type epitaxial layers 163 may also vary within the limits known in the art. Like the MQW structure 162, the p-type epitaxial layers 163 may also be gown in an MOCVD or HVPE epitaxy chamber. Incorporation of Mg during the growth of the p-type epitaxial layers 163 may be by way of introduction of cp₂Mg to the epitaxy chamber, for example. In an embodiment, the p-type epitaxial layers 163 are grown using the same epitaxial chamber as the MQW structure 162.

Additional layers (not depicted), such as, tunneling layers, n-type current spreading layers and further MQW structures (e.g., for stacked diode embodiments) may be disposed over the p-type epitaxial layers 163 in substantially the same manner described for the layers illustrated in the exemplary LED 100 or in any manner known in the art. Following the growth of the LED stack, conventional patterning and etching techniques are performed to expose regions of the bottom n-type epitaxial layer 115 and the p-type epitaxial layer(s) 163. Any contact metallization known in the art may then be applied to the exposed regions to form an n-type terminal 101 and a p-type terminal 102. In exemplary embodiments, the n-type terminal includes a contact, such as, but not limited to, Al/Au, Ti/Al/Ni/Au, Al/Pt/Au, or Ti/Al/Pt/Au. An exemplary p-type terminal includes a Ni/Au or Pd/Au contact. For either n-type or p-type contacts, a transparent conductor, such as Indium Tin Oxide (ITO), or others known in the art, may also be utilized.

The base layer stack 109 and the operations to form the base layer stack 109 are now described in greater detail. FIG. 1B is a flow diagram illustrating a nano masking method 106 for growing the base layer stack 109, in accordance with an embodiment of the present invention. FIG. 1B is describe in conjunction with FIG. 1C which depicts cross-sectional views of the evolution of the base layer stack 109 as particular operations in the nano masking method 106 are performed on the substrate 103, in accordance with an embodiment of the present invention.

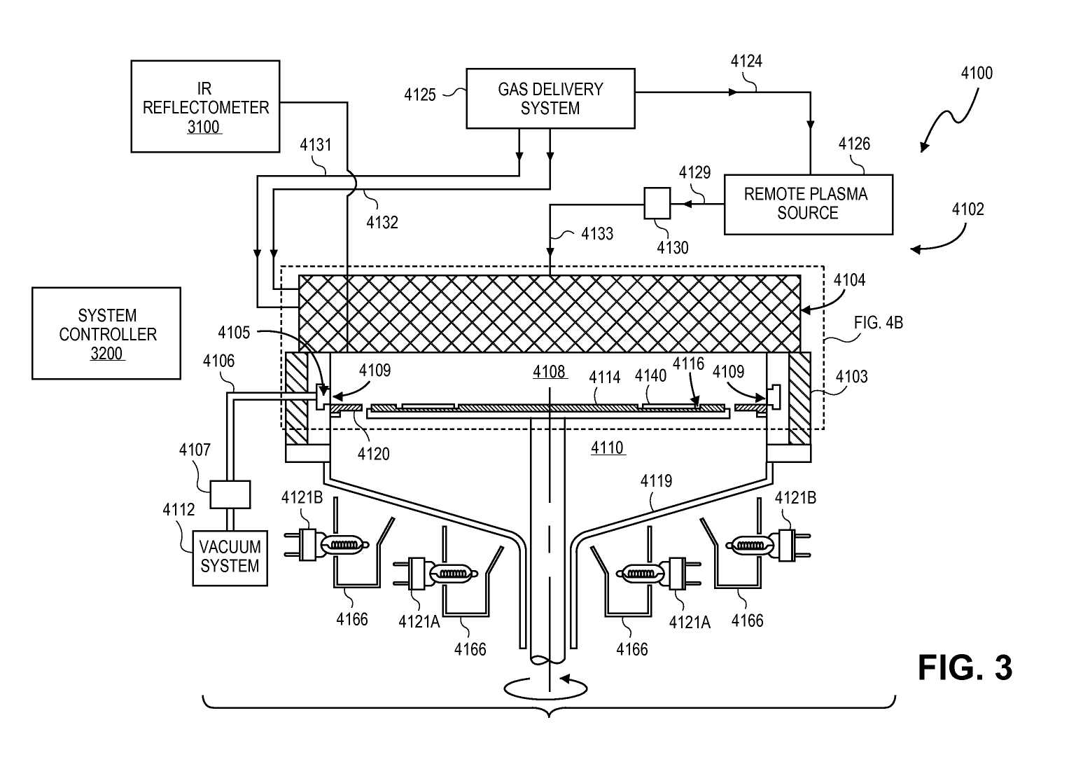

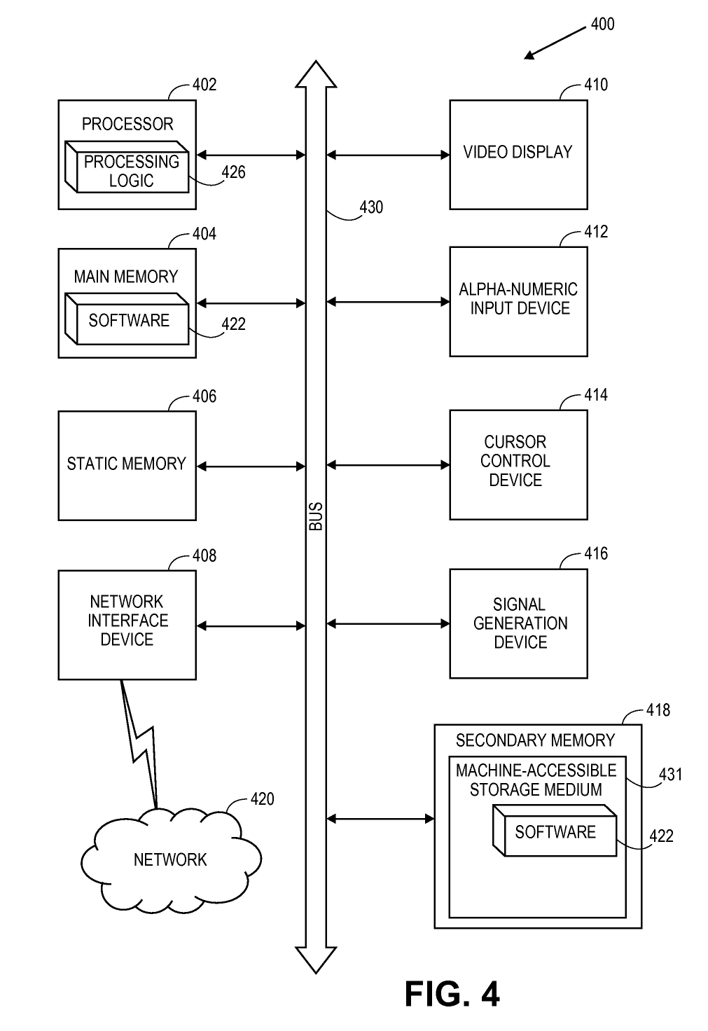

Referring to FIG. 1B, at operation 135 the substrate 103 is provided to a deposition chamber, such as those described elsewhere herein in reference to FIGS. 3 and 4. Alternatively any deposition chamber known in the art to be capable of performing epitaxial growth of III-V materials, such as a group III-nitrides like GaN may be utilized. In one embodiment, the substrate 103 provided at operation 135 is a bare sapphire substrate. The substrate 103 is then heated at operation 136, for example between about 500° C. and about 1,100° C., and typically between about 850° C. and about 1,100° C. While heating the substrate 103 may be exposed to a reducing environment, such as hydrogen (H₂), to remove contaminants from the substrate surface in preparation for film formation.

At operation 138 the buffer layer 105 is grown. Any of the materials described elsewhere herein for the buffer layer 105 may be grown at operation 138 using any group III source gas and group V source gas (e.g., metalorganic precursors) known in the art depending on the buffer material to be grown. For the exemplary GaN buffer layer, a Ga source gas is reacted with the first precursor is reacted with a first nitrogen source gas. In one embodiment, the first nitrogen source gas is ammonia (NH₃). In other embodiments, the first nitrogen source gas may be one or more active nitrogen species derived from a containing material such as nitrogen gas, nitrous oxide, hydrazine, diimide, hydrazoic acid, and the like. Generally, growth of the buffer layer 105 is at a lower temperature than is used for a bulk film growth. For example, in one GaN embodiment, the temperature of the substrate 103 is at a temperature between about 500° C. and about 950° C.

With the buffer layer 105 disposed on the substrate 103, as further illustrated in FIG. 1B, the nano masking method 106 (FIG. 1B) proceeds to the nucleation operation 140. Nucleation, also known as 3D growth, is to form crystalline material islands, nucleation sites or nuclei 141 over the buffer layer 105, as further illustrated in FIG. 1C. The morphology of the nuclei 141 varies with material system and growth conditions, but generally the islands form on the nucleation domains present in the buffer layer 105 with amorphous portions of the buffer layer 105 spacing apart the nuclei 141. Because of the discontinuous nature of the nuclei, a thickness characterization of a nucleation layer is inapplicable and instead nuclei formation may be characterized by a surface roughening which can be measured in-situ by a reduction in IR reflectivity of the substrate relative to the surface reflectivity immediately following formation of the buffer layer 105.

At the nucleation operation 140, the nuclei 141 are to be formed at a second temperature, higher than that for the buffer layer growth. The second temperature may further be higher than what is used for a bulk layer growth. As one example of growth temperature during the nucleation for a group III-nitride embodiment including a GaN buffer layer 105, GaN nuclei are formed at a temperature in the range of 1000° C. to 1100° C. In an embodiment, the nucleation operation utilizes a group V/group III source gas ratio (e.g., NH₃ to Ga precursor for GaN) that is relatively lower than for a bulk film growth in conjunction with a pressure that is relatively higher than for a bulk film growth. Typically, the nucleation operation 140 is performed for a predetermined time and in certain embodiments may be the nucleation operation 140 may be terminated upon reaching a predetermine threshold reduction in IR surface reflectivity.

Returning to FIG. 1B, following the nucleation operation 140, a growth stopper is formed around the nuclei at a nano masking operation 145. As further illustrated in FIG. 1C, the growth stopper 146 preferentially forms first on surfaces having lowest surface potential energy, which are generally the recessed areas between the nuclei 141. As long as the duration of the nano masking operation 145 is not too long, the growth stopper 146 can be made to leave a portion of a nucleation site exposed. For example, top surfaces of the nuclei may be considered to have the highest surface potential and the last regions to be covered by the growth stopper 146. Terminating the nano masking operation 145 before the growth stopper 146 completely covers each and every one of the nuclei 141 yields what is referred to herein as a “nano mask” which essentially covers the inverse regions of the buffer layer 105 as do the nuclei 141. The nano mask functionally serves to stop underlying dislocations from propagating into upper layers of the material stack. Also, the masking causes subsequent epitaxially growth to occur from the tops of the nuclei 141 which allows for better crystalline quality and reduced dislocation density. Surface morphology following formation of the nano mask remains rough with little, if any increase, in surface IR reflectivity from the reflectivity measured immediately following the nucleation operation 140.

The growth stopper 146 may be of any material known to hinder growth of the particular III-V material to be epitaxially grown from the nuclei 141. In group III-nitride embodiments, the growth stopper may be, but is not limited to, silicon nitride (SiNₓ) and silicon dioxide (SiO₂). In the preferred embodiment, the nano masking operation 145 is performed in the same deposition chamber as the nucleation operation 140. For such in-situ nano mask embodiments, the growth stopper is preferably SiNx as introduction of oxygen into a nondedicated epitaxial growth chamber poses technical difficulties.

In one group III-nitride embodiment, following growth of GaN nuclei at operation 140, at the nano masking operation 145 the group III source gas is replaced with a silicon source gas, such as a silane (SiH₄, Si₂H₆, etc.), while continuing to introduce the nitrogen source gas (e.g., NH₃) that was utilized during formation of the nucleation sites to form a SiNₓ nano mask. In one such embodiment, the flow rate of the NH₃ is maintained at the same level as employed in the nucleation operation 140 as being more than sufficient to deposit SiNₓ when combined with the silicon source gas. Exemplary substrate temperatures during the nano masking operation 145 are between about 850° C. and 1100° C. and may be at the same temperature as for the nucleation operation 140 or slightly lower (e.g., about 1000° C. where the nucleation is at 1100° C. as a transition between the nucleation operation 140 and a subsequent recovery operation 150). Deposition times may vary as dependent on the deposition rate a chamber achieves and the dimensions of the nuclei 141. Generally, the growth stopper 146 will be less than 500 nm, as a function of the nucleation site dimensions (e.g., height of 3D growth). It has been found that for certain GaN embodiments, a very thin growth stopper 146, on the order of 5-10 nm, is sufficient to provide significant improvement in crystal quality.

In other embodiments where a SiO₂ nano mask is to be formed at the nano masking operation 145, the substrate 103 may be transferred to a second deposition chamber configured for CVD of SiO₂, the nano mask formed ex-situ (but still without breaking vacuum), and then the substrate 103 transferred back to the group III-nitride deposition chamber (e.g., the chamber utilized for the nucleation operation 140 or a similar chamber).

Returning to FIG. 1B, the nano masking method 100 proceeds to operation 150 with epitaxial overgrowth or coalescence of the nuclei 141. The lateral overgrowth operation 150 is affected by the presence of the growth stopper 146 so that epitaxially grown material laterally extends from an upper portion of the nuclei 141 left uncovered by the growth stopper to bridge the plurality of the nuclei 141 above the growth stopper 146. As further shown in FIG. 1C, voids 147 are formed between the growth stopper 146 and the laterally overgrown epitaxial layer 151 because the lower region of the nuclei 141 is covered by the growth stopper 146 hindering lateral epitaxial growth at that location. In the exemplary group III-nitride material system, the bridging epitaxial layer grown from the nuclei 141 is undoped GaN to form an initial portion of the undoped layer 110 further depicted in FIG. 1A. Because the voids 147 are disposed between the buffer layer 105 and an undoped group III-nitride layer and will have an irregular shape, the voids 147 may advantageously serve as light scattering centers which can improve the light extraction efficiency of an LED, increasing brightness. The scattering is a result of the voids 147 having a refractive index contrast with the surrounding material (e.g., GaN).

The lateral overgrowth operation 150 may be performed to grow a range of material thicknesses, typically between 1 and 2 μm. Growth conditions during the lateral overgrowth operation 150 generally entails a group V/group III gas ratio (e.g. increased NH₃ partial pressure) that is relatively higher than is employed during the buffer growth operation 138 and may be further higher than is employed during a bulk film growth to improve the lateral growth rates. The lateral overgrowth may be performed with lower pressures than employed during the nucleation operation 140 with exemplary pressures being below 300 Torr, and more particularly between 100 and 150 Torr for GaN. In embodiments, the process pressure may further be lower than what is utilized for Growth temperatures at operation 150 are generally to be higher than employed during the buffer growth operation 138 and may be the same or lower than the for the nucleation operation 140. For the exemplary in-situ nano mask formation embodiments, the lateral overgrowth operation 150 may entail replacing the silicon source gas with a group III source gas, such as a Ga source gas for the GaN embodiments while maintaining the nitrogen source gas (NH₃) flow.

In particular embodiments, the lateral overgrowth operation 150 improves the surface morphology relative to that present after the nucleation operation 140 and remaining after the nano masking operation 145. When the nano mask is formed by a process having the proper duration (i.e., the growth stopper 146 is not covering to much of a give nucleation site and/or too great of a percentage of a population of nuclei having a size distribution), the lateral overgrowth achieves a full recovery of surface morphology with reflectance following the lateral overgrowth operation 150 becoming equal to the reflectivity immediately following the buffer growth operation 138. Thus, improvements in crystal quality may be achieved via the nano masking method 106 while still maintaining the surface morphology important to LED devices. Where the nano masking operation 145 is performed for too long of a duration, rendering the growth stopper 146 too thick, reflectance will not be fully recovered at operation 150. Further embodiments may therefore entail feedback control in which in-situ measurement of IR reflectance at operation 150 performed on a first substrate may be utilized to modify the duration of the nano masking operation 145 on a subsequent substrate.

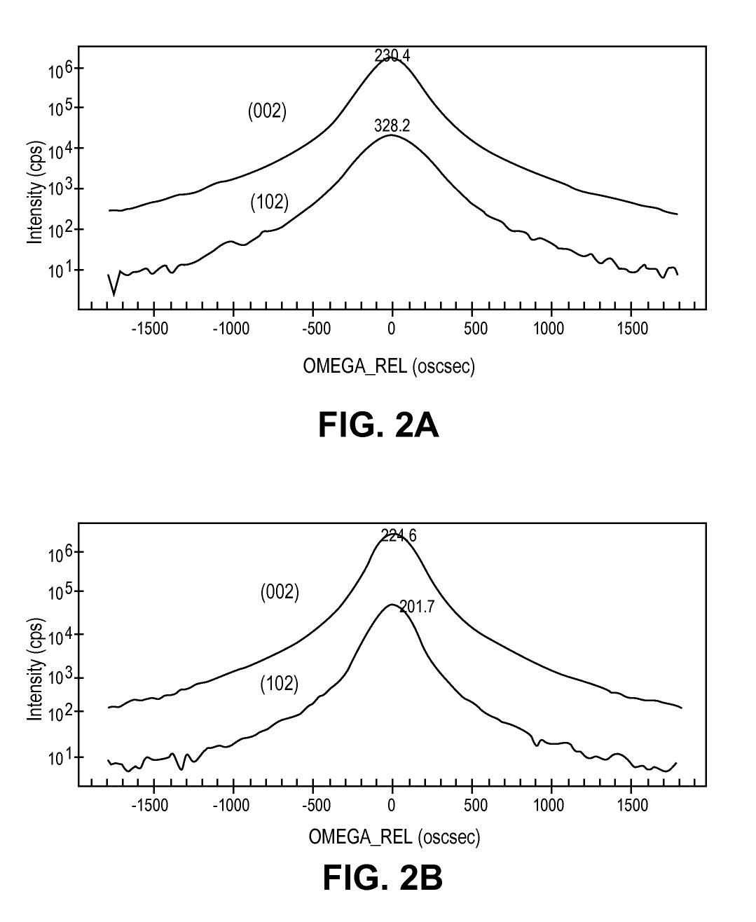

FIG. 2A is an XRD rocking curve for a GaN base layer stack grown using a conventional growth technique for comparison to FIG. 2B illustrating a GaN base layer stack 109 grown using the nano masking method 106 depicted in FIG. 1B, in accordance with an embodiment. For GaN, the full width half maximum (FWHM) value on the rocking curve for the (102) direction represents crystalline quality. As FIGS. 2A and 2B show, the nano masking method 106 reduces the FWHM from over 300 arc seconds to approximately 200 arc seconds. This reduction in FWHM has been found to be a function of the duration of the nano masking operation 145 with the growth stopper formed by shorter deposition times showing less of an reduction in FWHM than longer deposition times. Growth stopper thickness/deposition time may therefore be optimized empirically based on IR reflectance and XRD analysis.

Following the lateral growth operation 150, the nano masking method 106 may be completed at operation 160 with a high temperature bulk epitaxial growth over the laterally overgrown material 151. For example, the thickness of a laterally overgrown group III-nitride material may be increased at the bulk growth operation 160 by growing the group III-nitride to complete formation of the undoped GaN layer 110 at a growth temperature above that at which the lateral overgrowth is performed. With the base layer stack 109 then substantially complete the substrate may be removed from the deposition chamber, and fabrication of the remaining layers in the LED stack may proceed substantially as described in FIG. 1A, or as may otherwise be performed in the art.

With the nano masking method 106 described, deposition chambers configured to perform the nano masking method 106 are described in reference to the exemplary MOCVD chambers illustrated in FIG. 3. While MOCVD is the exemplary growth method used as a vehicle for succinctly describing embodiments of the present invention, it should be noted that other growth techniques and deposition chambers are also applicable. For example, alternative embodiments employ hydride vapor phase epitaxy (HVPE) and chambers configured to perform HVPE.

FIG. 3 depicts a schematic cross-sectional view of an MOCVD chamber which can be utilized in embodiments of the invention. Exemplary systems and chambers that may be adapted to practice the present invention are described in U.S. patent application Ser. No. 11/404,516, filed on Apr. 14, 2006, and Ser. No. 11/429,022, filed on May 5, 2006.

The MOCVD apparatus 4100 shown includes a chamber 4102, a gas delivery system 4125, a remote plasma source 4126, and a vacuum system 4112. The chamber 4102 includes a chamber body 4103 that encloses a processing volume 4108. A showerhead assembly 4104 is disposed at one end of the processing volume 4108, and a substrate carrier 4114 is disposed at the other end of the processing volume 4108. A lower dome 4119 is disposed at one end of a lower volume 4110, and the substrate carrier 4114 is disposed at the other end of the lower volume 4110. An exhaust ring 4120 may be disposed around the periphery of the substrate carrier 4114 to help prevent deposition from occurring in the lower volume 4110 and also help direct exhaust gases from the chamber 4102 to exhaust ports 4109. The lower dome 4119 may be made of transparent material, such as high-purity quartz, to allow light to pass through for radiant heating of the substrates 4140. The radiant heating may be provided by a plurality of inner lamps 4121A and outer lamps 4121B disposed below the lower dome 4119, and reflectors 4166 may be used to help control chamber 4102 exposure to the radiant energy provided by inner and outer lamps 4121A, 4121B. Additional rings of lamps may also be used for finer temperature control of the substrates 4140.

The substrate carrier 4114 may include one or more recesses 4116 within which one or more substrates 4140 may be disposed during processing. The substrate carrier 4114 may carry six or more substrates 4140. The substrate carrier 4114 may be formed from a variety of materials, including SiC or SiC-coated graphite. The substrate carrier 4114 may rotate about an axis during processing. In one embodiment, the substrate carrier 4114 may be rotated at about 2 RPM to about 100 RPM.

In one embodiment, one or more temperature sensors, such as pyrometers (not shown), may be disposed within the showerhead assembly 4104 to measure substrate 4140 and substrate carrier 4114 temperatures, and the temperature data may be sent to a controller (not shown) which can adjust power to separate lamp zones to maintain a predetermined temperature profile across the substrate carrier 4114. In another embodiment, an IR beam reflectance metrology unit 3100 may also be disposed to collected reflectance measurement data for one or more substrates during the epitaxial growth operations described herein.

The inner and outer lamps 4121A, 4121B may heat the substrates 4140 to a temperature of about 400 degrees Celsius to about 1200 degrees Celsius. It is to be understood that the invention is not restricted to the use of arrays of inner and outer lamps 4121A, 4121B. Any suitable heating source may be utilized to ensure that the proper temperature is adequately applied to the chamber 4102 and substrates 4140 therein. For example, in another embodiment, the heating source may comprise resistive heating elements (not shown) which are in thermal contact with the substrate carrier 4114.

A gas delivery system 4125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 4102. Different gases, such as precursor gases, carrier gases, purge gases, cleaning/etching gases or others may be supplied from the gas delivery system 4125 to separate supply lines 4131, 4132, and 4133 to the showerhead assembly 4104. The supply lines 4131, 4132, and 4133 may include shut-off valves and mass flow controllers or other types of controllers to monitor and regulate or shut off the flow of gas in each line. Reaction of process source gases at or near the substrate 4140 surface may deposit various metal nitride layers upon the substrate 4140, including GaN, aluminum nitride (AlN), and indium nitride (InN). Multiple metals may also be utilized for the deposition of other compound films such as AlGaN and/or InGaN. Additionally, dopants, such as silicon (Si) or magnesium (Mg), may be added to the films. The films may be doped by adding small amounts of dopant gases during the deposition process. For nano mask formation and for silicon doping of epitaxial layers, silane (SiH₄) or disilane (Si₂H₆) gases may be used, for example, and a dopant gas may include Bis(cyclopentadienyl)magnesium (Cp₂Mg or (C₅H₅)₂Mg) for magnesium doping.

A conduit 4129 may receive cleaning/etching gases from a remote plasma source 4126. The remote plasma source 4126 may receive gases from the gas delivery system 4125 via supply line 4124, and a valve 4130 may be disposed between the showerhead assembly 4104 and remote plasma source 4126. The valve 4130 may be opened to allow a cleaning and/or etching gas or plasma to flow into the showerhead assembly 4104 via supply line 4133 which may be adapted to function as a conduit for a plasma. In another embodiment, MOCVD apparatus 4100 may not include remote plasma source 4126 and cleaning/etching gases may be delivered from gas delivery system 4125 for non-plasma cleaning and/or etching using alternate supply line configurations to showerhead assembly 4104.

The remote plasma source 4126 may be a radio frequency or microwave plasma source adapted for chamber 4102 cleaning and/or substrate 4140 etching. Cleaning and/or etching gas may be supplied to the remote plasma source 4126 via supply line 4124 to produce plasma species which may be sent via conduit 4129 and supply line 4133 for dispersion through showerhead assembly 4104 into chamber 4102. Gases for a cleaning application may include fluorine, chlorine or other reactive elements.

In another embodiment, the gas delivery system 4125 and remote plasma source 4126 may be suitably adapted so that precursor gases may be supplied to the remote plasma source 4126 to produce plasma species which may be sent through showerhead assembly 4104 to deposit CVD layers, such as III-V films, for example, on substrates 4140.

A purge gas (e.g., nitrogen) may be delivered into the chamber 4102 from the showerhead assembly 4104 and/or from inlet ports or tubes (not shown) disposed below the substrate carrier 4114 and near the bottom of the chamber body 4103. The purge gas enters the lower volume 4110 of the chamber 4102 and flows upwards past the substrate carrier 4114 and exhaust ring 4120 and into multiple exhaust ports 4109 which are disposed around an annular exhaust channel 4105. An exhaust conduit 4106 connects the annular exhaust channel 4105 to a vacuum system 4112 which includes a vacuum pump (not shown). The chamber 4102 pressure may be controlled using a valve system 4107 which controls the rate at which the exhaust gases are drawn from the annular exhaust channel 4105.

As further depicted in FIG. 3, the MOCVD apparatus 4100 includes an system controller 3200 coupled to the IR reflectometer unit 3100 as well as process control points within the MOCVD apparatus 4100, such as but not limited to the valve system 4107, the gas shut-off valves and mass flow controllers in the gas delivery system 4125. In an embodiment the system controller 3200 is configured, for example by executable code, to introduce a group III source gas and a nitrogen source gas to epitaxially grow islands of a group III-nitride material over a buffer layer disposed on the substrate 4140. The system controller 3200 is further to replace the group III source gas introduced into the deposition chamber during formation of the island nuclei with a silicon source gas while continuing to introduce the nitrogen source gas utilized during formation of the nuclei to form a growth stopper between the nuclei. The system controller 3200 is further to replace the silicon source gas with the group III source gas to bridge the nuclei above the growth stopper with a laterally overgrown epitaxial layer of the group III-nitride material. In particular embodiments, the system controller 3200 is further to cause the IR reflectometry unit 3100 to measure a reflectance of both the buffer layer the laterally overgrown epitaxial layer as each is grown or immediately thereafter.

The MOCVD apparatus 4100 or a deposition apparatus employing an alternative technology (e.g., a HVPE chamber) may be used in a processing system such as a cluster tool that is adapted to process substrates and analyze the results of the processes performed on the substrate. The cluster tool is a modular system comprising multiple chambers that perform various processing steps that are used to form an electronic device. The cluster tool may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif. Alternatively, the MOCVD apparatus 4100 or an alternative technology deposition apparatus (e.g., a HVPE chamber) may be adapted into an in-line processing apparatus.

FIG. 4 illustrates a diagrammatic representation of a machine in the exemplary form of a computer system 400 which may be utilized by the system controller 3200 to control one or more of the operations, process chambers or multi-chambered processing platforms described herein. In alternative embodiments, the machine may be connected (e.g., through network 420) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC) or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 400 includes a processor 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a secondary memory 418 (e.g., a data storage device), which communicate with each other via a bus 430.

The processor 402 represents one or more general-purpose processing devices such as a microprocessor, central processing unit, or the like. More particularly, the processor 402 may be a complex instruction set computing (CISC) microprocessor, reduced instruction set computing (RISC) microprocessor, very long instruction word (VLIW) microprocessor, processor implementing other instruction sets, or processors implementing a combination of instruction sets. The processor 402 may also be one or more special-purpose processing devices such as an application specific integrated circuit (ASIC), a field programmable gate array (FPGA), a digital signal processor (DSP), network processor, or the like. The processor 402 is configured to execute the processing logic 426 for performing the process operations discussed elsewhere herein.

The computer system 400 may further include a network interface device 408. The computer system 400 also may include a video display unit 410 (e.g., a liquid crystal display (LCD) or a cathode ray tube (CRT)), an alphanumeric input device 412 (e.g., a keyboard), a cursor control device 414 (e.g., a mouse), and a signal generation device 416 (e.g., a speaker).

The secondary memory 418 may include a machine-accessible storage medium (or more specifically a computer-readable storage medium) 431 on which is stored one or more sets of instructions (e.g., software 422) embodying any one or more of the methods or functions described herein. The software 422 may also reside, completely or at least partially, within the main memory 404 and/or within the processor 402 during execution thereof by the computer system 400, the main memory 404 and the processor 402 also constituting machine-readable storage media.

The machine-accessible storage medium 431 may further be used to store a set of instructions for execution by a processing system and that cause the system to perform any one or more of the embodiments of the present invention. Embodiments of the present invention may further be provided as a computer program product, or software, that may include a machine-readable storage medium having stored thereon instructions, which may be used to program a computer system (or other electronic devices) to perform a process according to the present invention. A machine-readable storage medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, and other such non-transitory storage media known in the art.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A method for epitaxially growing a semiconductor stack on a substrate, comprising:
providing a substrate in a deposition chamber;
forming a buffer layer over the substrate;
epitaxially growing islands of a group III-nitride material over the buffer layer to form nuclei;
depositing a growth stopper between the nuclei;
epitaxially overgrowing the group III-nitride material laterally from an upper region of the nuclei, the upper region left uncovered by the growth stopper to bridge the nuclei above the growth stopper.

2. The method of claim 1, wherein depositing the growth stopper further comprises replacing the group III source gas introduced into the deposition chamber during formation of the nuclei with a silicon source gas while continuing to introduce into the deposition chamber the nitrogen source gas utilized during formation of the nuclei.

3. The method as in claim 1, wherein the growth stopper comprises silicon nitride or silicon oxide.

4. The method as in claim 3, wherein the group III-nitride material comprises GaN and wherein the growth stopper comprises silicon nitride.

5. The method as in claim 1, further comprising:
increasing the thickness of the laterally overgrown group III-nitride material by growing the group III-nitride at a growth temperature above that at which the lateral overgrowth is performed and;
removing the substrate from the epitaxy chamber.

6. The method as in claim as in claim 1, further comprising:
forming an n-type layer and a p-type layer comprising the group III-nitride material over the laterally overgrown group III-nitride material, and
forming a multiple quantum well structure disposed between the n-type layer and p-type layer.

7. The method as in claim 1, wherein forming the buffer layer further comprises introducing a nitrogen source gas and a group III source gas at a first VIII ratio into the deposition chamber at a first growth pressure while the substrate is at a first growth temperature;
wherein epitaxially growing islands of the group III-nitride material further comprises introducing the nitrogen source gas and the group III source gas at a second VIII ratio, lower than the first ratio, at a second growth pressure higher than the first growth pressure, and at a second temperature higher than the first growth temperature;
wherein depositing the growth stopper further comprises replacing the group III source gas with a silicon source gas while continuing to introduce into the deposition chamber the nitrogen source gas; and
wherein epitaxially overgrowing the group III-nitride material laterally further comprises introducing the nitrogen source gas and the group III source gas at a third VIII ratio higher than the second ratio, at a third growth pressure lower than the second growth pressure, and at a third temperature higher than the first temperature.

8. The method of claim 1, wherein the nuclei are grown directly on the buffer layer, wherein the growth stopper is deposited directly on the buffer layer.

9. The method of claim 1, wherein epitaxially overgrowing the group III-nitride material laterally forms a void between the laterally overgrown group III-nitride material and the growth stopper.

10. The method of claim 9, wherein the nuclei are grown directly on the buffer layer, wherein the growth stopper is deposited directly on the buffer layer and wherein epitaxially overgrowing the group III-nitride material laterally forms a void between the laterally overgrown group III-nitride material and the growth stopper to dispose the void between the buffer layer and an undoped group III-nitride layer.

11. A light emitting diode (LED) semiconductor material stack comprising:
a substrate;
a buffer layer disposed over the substrate, the buffer layer comprises a group III-nitride;
a nucleation layer disposed over the buffer, the nucleation layer comprising a plurality of nuclei separated from each other by a growth stopper; and
an n-type and a p-type group III-nitride layer disposed over the nucleation layer with a multiple quantum well structure disposed there between.

12. The LED stack of claim 11, wherein the growth stopper comprises silicon nitride or silicon dioxide.

13. The LED stack of claim 12, wherein the group III-nitride material comprises GaN and wherein the growth stopper comprises silicon nitride.

14. The LED stack of claim 11, further comprising an undoped group III-nitride layer disposed over the growth stopper with a void disposed there between.

15. The LED stack of claim 14, wherein the nuclei are disposed directly on the buffer layer, wherein the growth stopper is disposed directly on the buffer layer and wherein a group III-nitride material layer disposed below the n-type group III-nitride layer laterally bridges the void.

16. The LED stack of claim 11, wherein the thickness of the growth stopper is less than 500 nm.

17. A light emitting diode (LED) comprising the light emitting diode (LED) semiconductor material stack of claim 10; and
a first terminal coupled to the n-type layer; and
a second terminal coupled to the p-type layer.

18. A system for epitaxially growing a semiconductor stack on a substrate, the system comprising:
a deposition chamber coupled with a group III source gas, a nitrogen source gas, and a silicon source gas; and
a system controller to introduce the group III source gas and the nitrogen source gas to epitaxially grow islands of a group III-nitride material over a buffer layer and form nuclei, the system controller further to replace the group III source gas introduced into the deposition chamber during formation of the nuclei with a silicon source gas while continuing to introduce into the deposition chamber the nitrogen source gas utilized during formation of the nuclei to form a growth stopper between the nuclei, and the system controller further to replace the silicon source gas with the group III source gas to bridge the nuclei above the growth stopper with a laterally overgrown epitaxial layer of the group III-nitride material.

19. The system of claim 18, further comprising an IR reflectometer to measure a reflectance of both the buffer layer the laterally overgrown epitaxial layer.

20. A computer readable storage media with instructions stored thereon, which when executed by a processing system, cause the system to perform the method of claim 1.
